(19) United States
(12) Patent Application Publication
(10) Pub. No.: US 2026/0182022 A1
(43) Pub. Date: Jun. 25, 2026

(54) SEMICONDUCTOR DEVICE

(71) Applicant: Samsung Electronics Co., Ltd., Suwon-si (KR)

(72) Inventors: Jinchan YUN, Suwon-si (KR); Sangwoo HAN, Suwon-si (KR); Jae Hyun PARK, Suwon-si (KR); Juhun PARK, Suwon-si (KR); Hongju PARK, Suwon-si (KR); Hyeji YOON, Suwon-si (KR); Jae Won JEONG, Suwon-si (KR); Kyuman HWANG, Suwon-si (KR)

(21) Appl. No.: 19/263,699

(22) Filed: Jul. 9, 2025

(30) Foreign Application Priority Data
Dec. 23, 2024 (KR) 10-2024-0194440

(51) Int. Cl. H10D 84/85; H10D 64/23; H10D 84/01

(52) U.S. Cl. CPC H10D 84/856; H10D 64/254; H10D 84/0167; H10D 84/017; H10D 84/0186; H10D 84/851

(57) ABSTRACT

Provided is a semiconductor device including a lower insulating layer, a lower channel pattern on the lower insulating layer, an upper channel pattern, a lower gate structure surrounding the lower channel pattern, an upper gate structure surrounding the upper channel pattern, a first lower source/drain pattern on the lower gate structure, a first upper source/drain pattern on the upper gate structure, a first spacer on the first upper source/drain pattern, a first source/drain contact, extending through the first spacer and the first upper source/drain pattern, and connected to the first upper source/drain pattern and the first lower source/drain pattern, a second lower source/drain pattern on the lower gate structure, a second upper source/drain pattern on the upper gate structure, a first interlayer dielectric on the second upper source/drain pattern, and a second source/drain contact extending through the first interlayer dielectric, and connected to the second upper source/drain pattern.

### CROSS-REFERENCE TO RELATED APPLICATION

This application claims priority to Korean Patent Application No. 10-2024-0194440, filed in the Korean Intellectual Property Office on Dec. 23, 2024, the entire contents of which are hereby incorporated by reference.

### BACKGROUND

### Field

The present disclosure relates to a semiconductor device.

### Description of Related Art

A semiconductor device is a core component used in an electronic device to control or amplify an electrical signal, and various types of semiconductor devices can be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

The semiconductor device includes an integrated circuit including a plurality of transistors. As the size and design rules of semiconductor devices are gradually reduced, the scale down of transistors is also gradually accelerating. The reduced size of the transistor may result in deterioration of the operating characteristics of the semiconductor device. Accordingly, various methods are being studied to form semiconductor devices with better performance, while overcoming the limitations caused by high integration of semiconductor devices.

### SUMMARY

To address one or more issues (e.g., the issues described above and/or other issues not explicitly described herein), the present disclosure provides a semiconductor device with improved integration density and electrical characteristics.

According to some aspects of the present disclosure, a semiconductor device is provided, which may include a lower insulating layer, a lower channel pattern stacked on the lower insulating layer in a first direction, an upper channel pattern spaced apart from the lower channel pattern in the first direction, a lower gate structure surrounding the lower channel pattern, an upper gate structure surrounding the upper channel pattern, a first lower source/drain pattern disposed on a first side of the lower gate structure in a second direction that intersects the first direction, a first upper source/drain pattern spaced apart from the first lower source/drain pattern in the first direction and disposed on a first side of the upper gate structure in the second direction, a first spacer disposed on the first upper source/drain pattern, a first source/drain contact extending along a first side surface of the first spacer in the first direction, extending through the first spacer and the first upper source/drain pattern, and connected to the first upper source/drain pattern and the first lower source/drain pattern, a second lower source/drain pattern disposed on a second side of the lower gate structure in the second direction, a second upper source/drain pattern spaced apart from the second lower source/drain pattern in the first direction and disposed on a second side of the upper gate structure in the second direction, a first interlayer dielectric disposed on the second upper source/drain pattern, and a second source/drain contact extending along a side surface of the first interlayer dielectric in the first direction, extending through the first interlayer dielectric, and connected to the second upper source/drain pattern, in which a thickness of the first spacer in a second direction is different from a thickness of the first interlayer dielectric in the second direction, the first side of the lower gate structure and the first side of the upper gate structure face a first side of the semiconductor device in the second direction, and the second side of the lower gate structure and the second side of the upper gate structure face a second side of the semiconductor device opposite the first side of the semiconductor device in the second direction.

According to some aspects, a semiconductor device is provided, which may include a lower insulating layer, a lower channel pattern stacked on the lower insulating layer in a first direction, an upper channel pattern spaced apart from the lower channel pattern in the first direction, a lower gate structure surrounding the lower channel pattern, an upper gate structure surrounding the upper channel pattern, a first lower source/drain pattern disposed on a first side of the lower gate structure in a second direction that intersects the first direction, and a second lower source/drain pattern disposed on a second side of the lower gate structure in the second direction, a first upper source/drain pattern disposed on a first side of the upper gate structure in the second direction and a second upper source/drain pattern disposed on a second side of the upper gate structure, in the second direction, a first spacer disposed on the first upper source/drain pattern, a first interlayer dielectric disposed on the second upper source/drain pattern, a first source/drain contact extending along a first side surface of the first spacer in the first direction, the first source/drain contact extending through the first spacer and the first upper source/drain pattern, and connected to the first upper source/drain pattern, in which the first source/drain contact may be in contact with an upper surface of the first lower source/drain pattern, and a second source/drain contact extending along a side surface of the first interlayer dielectric in the first direction, extending through the first interlayer dielectric, and connected to the second upper source/drain pattern, in which the first spacer and the first interlayer dielectric are formed of different materials, the second source/drain contact may overlap with at least a portion of the second upper source/drain pattern in the second direction, the first side of the lower gate structure and the first side of the upper gate structure face a first side of the semiconductor device in the second direction, and the second side of the lower gate structure and the second side of the upper gate structure face a second side of the semiconductor device opposite the first side of the semiconductor device in the second direction.

According to some aspects, a semiconductor device is provided, which may include a lower insulating layer, a lower channel pattern stacked on the lower insulating layer in a first direction, an upper channel pattern spaced apart from the lower channel pattern in the first direction, a lower gate structure surrounding the lower channel pattern, an upper gate structure surrounding the upper channel pattern, a first lower source/drain pattern disposed on a first side of the lower gate structure in a second direction that intersects the first direction, a second lower source/drain pattern disposed on a second side of the lower gate structure in the second direction, a first upper source/drain pattern spaced apart from the first lower source/drain pattern in the first direction and disposed on a first side of the upper gate structure in the second direction, a second upper source/drain pattern spaced apart from the second lower source/drain pattern in the first direction and disposed on a second side of the upper gate structure in the second direction, a first interlayer dielectric disposed on the second upper source/drain pattern, a second interlayer dielectric disposed between the lower channel pattern and the upper channel pattern, an etch stop layer disposed on the first upper source/drain pattern, a first spacer disposed on the etch stop layer, a first source/drain contact extending along a side surface of the first spacer and the etch stop layer in the first direction, extending through the first spacer, the etch stop layer, the first upper source/drain pattern, and the second interlayer dielectric, and connected to the first upper source/drain pattern and the first lower source/drain pattern, and a second source/drain contact extending along a side surface of the first interlayer dielectric in the first direction, extending through the first interlayer dielectric, and connected to the second upper source/drain pattern, in which a thickness of the first spacer in the second direction is different from a thickness of the first interlayer dielectric in the second direction, the first side of the lower gate structure and the first side of the upper gate structure face a first side of the semiconductor device in the second direction, and the second side of the lower gate structure and the second side of the upper gate structure face a second side of the semiconductor device opposite the first side of the semiconductor device in the second direction.

According to some aspects, by implementing the source/drain contact that extends in the first direction through the upper source/drain pattern and electrically connected to the upper source/drain pattern and the lower source/drain pattern, various integrated circuits can be implemented without an additional wiring process. As a result, the integration density and electrical characteristics of the semiconductor device can be improved.

According to some aspects, the source/drain contact extending in the first direction through the upper source/drain pattern can be implemented without depositing a separate sacrificial layer on the upper source/drain pattern. As a result, the electrical characteristics of the semiconductor device can be improved.

### BRIEF DESCRIPTION OF THE DRAWINGS

The above and other objects, features and advantages of the present disclosure will become more apparent to those of ordinary skill in the art by describing in detail exemplary aspects thereof with reference to the accompanying drawings, in which:

FIG. 1 is an example layout diagram provided to explain a semiconductor device according to some aspects;

FIG. 2 is a cross-sectional view illustrating the semiconductor device taken along line A-A of FIG. 1;

FIG. 3 is a cross-sectional view illustrating the semiconductor device taken along line A-A of FIG. 1;

FIG. 4 is a cross-sectional view illustrating the semiconductor device taken along line A-A of FIG. 1;

FIG. 5 is a cross-sectional view illustrating the semiconductor device taken along line A-A of FIG. 1;

FIG. 6 is a cross-sectional view illustrating the semiconductor device taken along line B-B of FIG. 1;

FIG. 7 is an example circuit diagram provided to explain a semiconductor device according to some aspects;

FIGS. 8 to 19 are diagrams illustrating intermediate stages of a method for manufacturing a semiconductor device according to some aspects; and

FIG. 20 is a schematic block diagram illustrating an electronic device including a semiconductor device according to some aspects.

### DETAILED DESCRIPTION

A semiconductor device according to some aspects of the present disclosure will be described in detail with reference to the drawings. Certain aspects will be disclosed herein as examples. Accordingly, the disclosure is not limited to certain aspects and may be implemented in various other forms. Each of the aspects provided herein is not excluded from being combined with another aspect provided herein or not provided herein, but consistent with the disclosure, or with one or more features of another aspect. For example, even when elements described in a certain example embodiment are not described in another example embodiment, it may be understood that the elements are associated with the other example embodiments unless otherwise stated in the description. In addition, it should be understood that all descriptions of principles, aspects, and example embodiments are intended to include their structural and functional equivalents. In addition, these equivalents should be understood to include not only currently well-known equivalents but also equivalents to be developed in the future, for example, all devices to be invented to perform the same function regardless of structure. For example, the material forming the contact or via may not be limited to the metals exemplified herein, provided that it is consistent with the principles of this disclosure.

Items described in the singular herein may be provided in plural, as can be seen, for example, in the drawings. Thus, the description of a single item that is provided in plural should be understood to be applicable to the remaining plurality of items unless context indicates otherwise.

When an element, a component, a layer, a pattern, a structure, a region, etc. (hereinafter collectively referred to as “component”) of a semiconductor device are referred to as being “over,” “above,” “on,” “cover,” “covering,” “overlap,” “overlapping,” “stacked,” “below,” “beneath,” “connected to,” or “coupled to” another component of the semiconductor device, that component may be directly over, above, on, covering, overlapping, stacked, below, under, beneath, connected to, or coupled to the other component, or with an intermediate component existing therebetween. When an element is referred to as “contacting” or “in contact with” another element (or using any form of the word “contact”), there are no intervening elements present at the point of contact. An element “over,” “above,” “on,” “cover,” “covering,” “overlap,” “overlapping,” “stacked,” “below,” “beneath,” “connected to,” or “coupled to” another element need not cover an entire top surface of an element below to be considered “on” or “over” or “stacked” over or “covering” or “overlapping”.

In the present description, spatially relative terms such as “over,” “above,” “on,” “covering,” “overlapping,” “upper,” “below,” “under,” “beneath,” “lower,” “top,” and “bottom” may be used for convenience of explanation in describing the relationship between one component and another as illustrated in the drawings. It will be understood that the spatially relative terms are intended to encompass other directions of the semiconductor device in use or operation in addition to the directions depicted in the drawings. For example, if the semiconductor device is flipped in the drawing, a component described as being “below” or “beneath” of another component may face “above” another component, and “top” or “upper” surface of the component may be the “bottom” or “lower” surface of the component. Therefore, according to the situation, the term “below” may include both upper and lower directions, and the term “top” may include both top and bottom. In this way, the semiconductor device may be oriented (e.g., rotated 90 degrees or in another direction), and the spatially relative descriptions used herein may be interpreted accordingly.

In addition, in the present description, the same reference numerals may refer to the same components.

In the present description, a semiconductor device according to some aspects may include or be a MOSFET, and more specifically, may include or be any three-dimensional multi-stack semiconductor device referred to as a gate-all-around transistor (GAA), a multi-bridge channel FET (MBCFET), or a FinFET. In addition, the semiconductor device may further include a tunneling transistor (tunneling FET), a 3D Stack Field Effect Transistor (3DSFET), a Complementary Field Effect Transistor (CFET), etc.

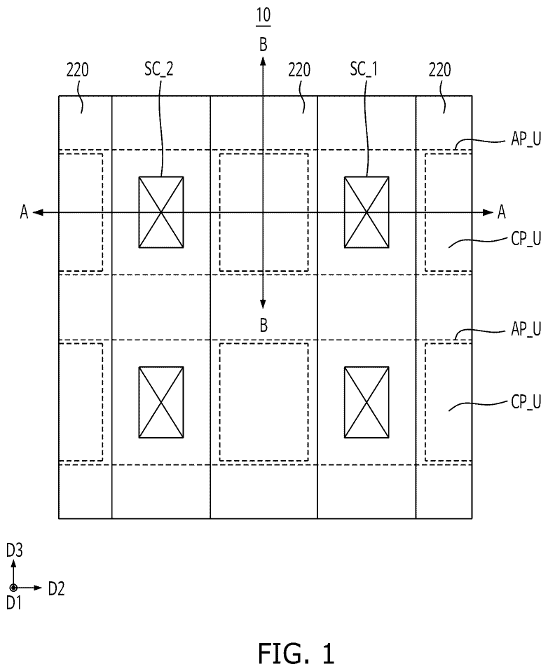

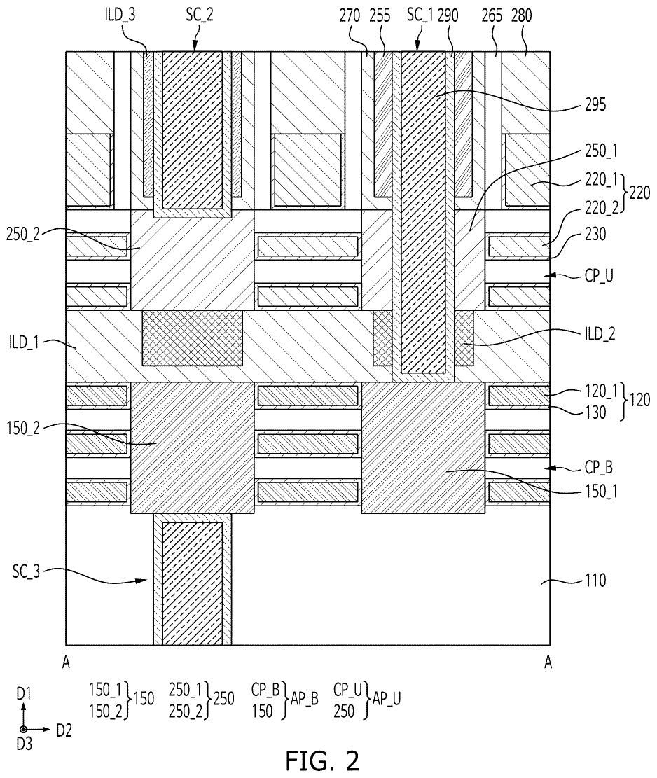

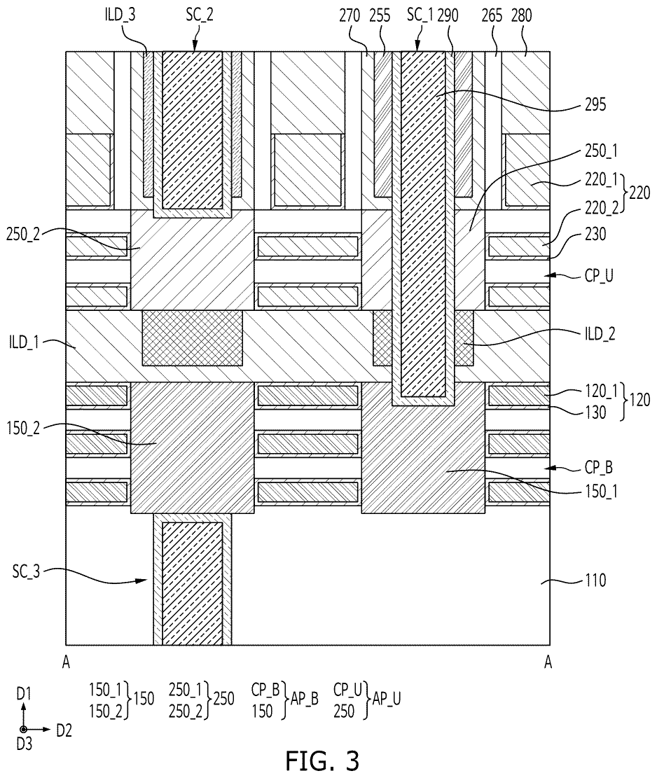

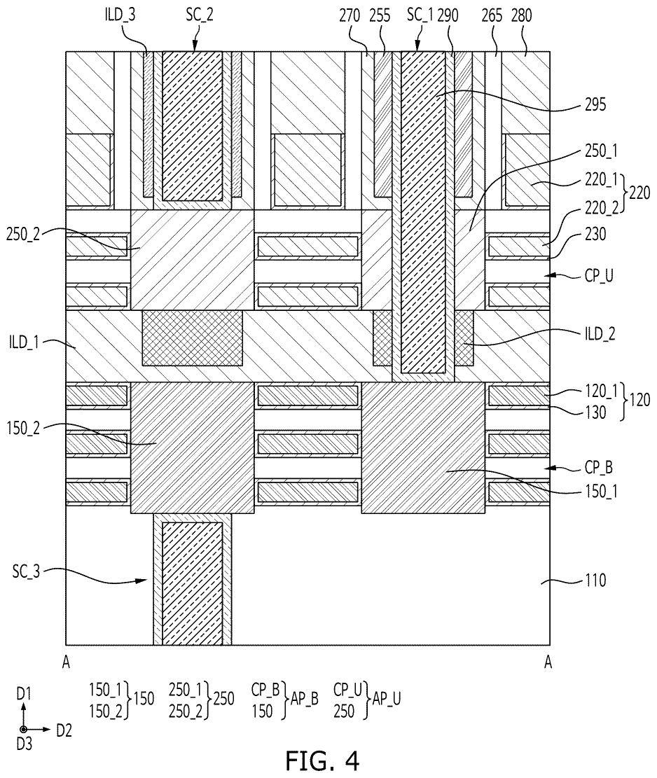

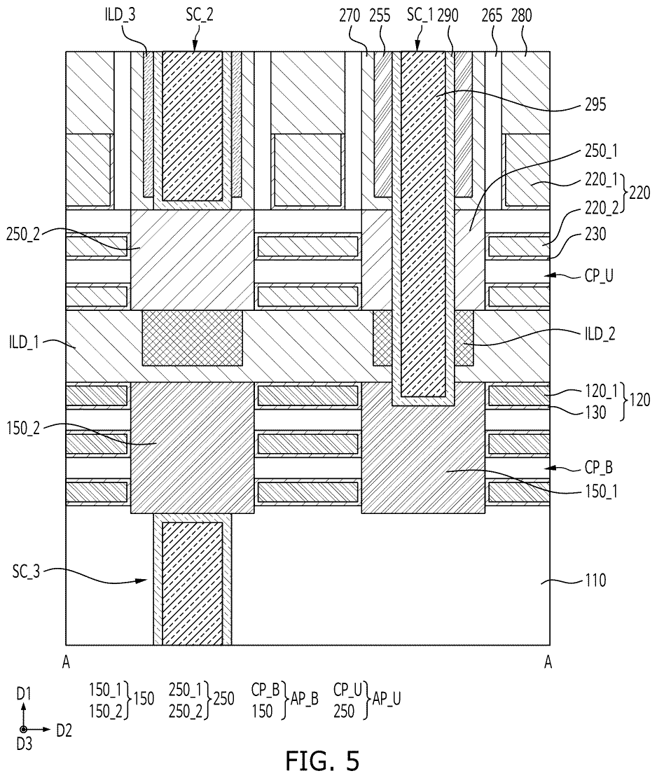

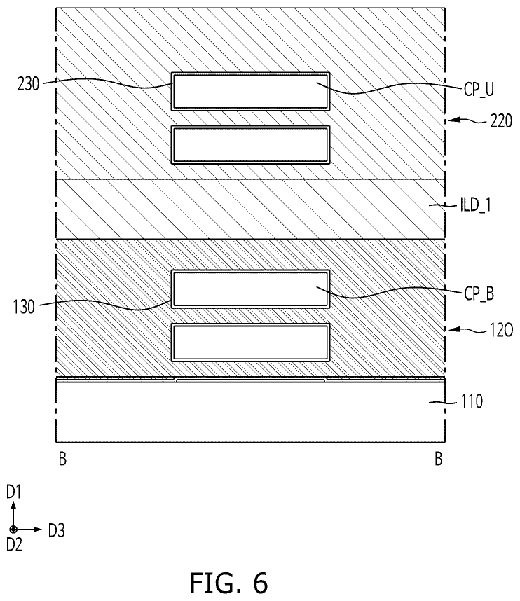

FIG. 1 is an example layout diagram provided to explain a semiconductor device 10 according to some aspects. FIG. 2 is a cross-sectional view illustrating the semiconductor device 10 taken along line A-A of FIG. 1. FIG. 3 is a cross-sectional view illustrating another embodiment of the semiconductor device 10 taken along line A-A of FIG. 1. FIG. 4 is a cross-sectional view illustrating another embodiment of the semiconductor device 10 taken along line A-A of FIG. 1. FIG. 5 is a cross-sectional view illustrating yet another embodiment of the semiconductor device 10 taken along line A-A of FIG. 1. FIG. 6 is a cross-sectional view illustrating the semiconductor device 10 taken along line B-B of FIG. 1.

For convenience of description, FIG. 1 illustrates only an upper active pattern AP_U, an upper channel pattern CP_U, an upper gate structure 220, a first source/drain contact SC_1, and a second source/drain contact SC_2. Referring to FIGS. 1 to 6, the semiconductor device 10 according to some aspects may include a lower insulating layer 110, a lower active pattern AP_B, a lower gate structure 120, the upper active pattern AP_U, the upper gate structure 220, a first spacer 255, and source/drain contacts SC_1, SC_2, SC_3, etc.

For example, the lower insulating layer 110 may include at least one of silicon oxide, silicon nitride, silicon oxynitride, and a low-k material. For example, the low-k material may include at least one of a fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, and mesoporous silica. However, aspects are not limited to the above. Although the lower insulating layer 110 is illustrated as a single layer, this is only for convenience of description and aspects are not limited thereto. For example, the lower insulating layer 110 may include a plurality of layers.

The lower active pattern AP_B and the lower gate structure 120 may be disposed on the lower insulating layer 110. The lower active pattern AP_B may extend in a second direction D2. The lower active pattern AP_B may be a multi-channel active pattern. The lower active pattern AP_B may include a lower channel pattern CP_B and a lower source/drain pattern 150.

The lower channel pattern CP_B may be stacked on the lower insulating layer 110 in a first direction D1. The lower channel pattern CP_B may be disposed to be spaced apart from another adjacent lower channel pattern CP_B in the second direction D2 that intersects with the first direction D1. For example, the second direction D2 may be perpendicular to the first direction D1. The lower channel patterns CP_B may be spaced apart from each other in the first direction D1. The first direction D1 may be a direction perpendicular to an upper surface of the lower insulating layer 110. The lower channel pattern CP_B may have a nanosheet shape. Unlike the illustration, the number of lower channel patterns CP_B may not be limited.

The lower channel pattern CP_B may include one of an elemental semiconductor material such as silicon (Si) or silicon germanium (SiGe), a group IV-IV compound semiconductor, or a group III-V compound semiconductor. For example, the group IV-IV compound semiconductor may be a binary compound or a ternary compound including at least two or more of carbon (C), silicon (Si), germanium (Ge), and tin (Sn). The group III-V compound semiconductor may be, for example, one of a binary compound, a ternary compound, or a quaternary compound formed by a combination of at least one of aluminum (Al), gallium (Ga) and indium (In) as a group III element and one of phosphorus (P), arsenic (As), and antimony (Sb) as a group V element.

The lower source/drain pattern 150 may be disposed on the lower insulating layer 110. The lower source/drain pattern 150 may be disposed on one side of the lower channel pattern CP_B. The lower source/drain pattern 150 may be disposed on one side of the lower gate structure 120. The lower source/drain pattern 150 may be connected to the lower channel pattern CP_B. A portion of a sidewall of the lower source/drain pattern 150 may be in contact with the lower channel pattern CP_B. Another portion of the sidewall of the lower source/drain pattern 150 may be in contact with the lower gate structure 120. The lower source/drain pattern 150 may connect the lower channel patterns CP_B stacked in the first direction D1. The lower source/drain pattern 150 may be disposed between a plurality of adjacent lower channel patterns CP_B spaced apart from each other in the second direction D2 that intersects with the first direction D1.

The lower source/drain pattern 150 may be disposed on one side of the lower gate structure 120. The lower source/drain pattern 150 may be disposed between a plurality of adjacent lower gate structures 120 in the second direction D2 that intersects with the first direction D1.

The lower source/drain pattern 150 may include for example, a first lower source/drain pattern 150_1 and a second lower source/drain pattern 150_2. The first lower source/drain pattern 150_1 and the second lower source/drain pattern 150_2 may be disposed on one side of the lower gate structure 120. The first lower source/drain pattern 150_1 and the second lower source/drain pattern 150_2 may be spaced apart from each other in the second direction D2. Each of the first lower source/drain pattern 150_1 and the second lower source/drain pattern 150_2 may be disposed between a plurality of lower channel patterns CP_B spaced apart from each other in the second direction D2. Alternatively, each of the first lower source/drain pattern 150_1 and the second lower source/drain pattern 150_2 may be disposed between the plurality of lower gate structures 120 spaced apart from each other in the second direction D2. For example, the first lower source/drain pattern 150_1 may be disposed on one side of the lower gate structure 120, in the second direction. For example, the second lower source/drain pattern 150_2 may be disposed on the other side of the lower gate structure 120, in the second direction.

The lower source/drain pattern 150 may be a semiconductor material. For example, the lower source/drain pattern 150 may include an element semiconductor material such as silicon (Si) or germanium (Ge). For example, the lower source/drain pattern 150 may include a binary compound or a ternary compound including at least two of carbon (C), silicon (Si), germanium (Ge), and tin (Sn), or a compound of these doped with a group IV element. For example, the lower source/drain pattern 150 may include silicon (Si), silicon-germanium (SiGe), germanium (Ge), silicon carbide (SiC), etc., but is not limited thereto.

The lower source/drain pattern 150 may include impurities doped into a semiconductor material. The doped impurities may include at least one of boron (B), phosphorus (P), carbon (C), arsenic (As), antimony (Sb), bismuth (Bi), and oxygen (O), but aspects are not limited thereto.

Although the lower source/drain pattern 150 is illustrated as a single layer, this is only for convenience of description, and aspects are not limited thereto. In some aspects, the lower source/drain pattern 150 may include a plurality of layers including different materials. In another aspect, the lower source/drain pattern 150 may be the same material, and may include a plurality of layers having different concentrations of constituent materials.

The lower gate structure 120 may be disposed on the lower insulating layer 110. The lower gate structure 120 may surround the lower channel pattern CP_B. The lower gate structure 120 may include a lower gate electrode 120_1 and a lower gate dielectric 130. The lower gate electrode 120_1 may be disposed on the lower insulating layer 110 and may extend in a third direction D3 that intersects with the first direction D1 and the second direction D2. For example, the third direction D3 may be perpendicular to the first direction D1 and the second direction D2. The lower gate electrode 120_1 may surround the lower channel pattern CP_B. For example, the lower gate electrode 120_1 may surround an upper surface, a lower surface, and both side surfaces of the lower channel pattern CP_B. The upper and lower surfaces of the lower channel pattern CP_B may refer to surfaces that intersect with the first direction D1, and both side surfaces of the lower channel pattern CP_B may refer to surfaces that intersect with the third direction D3.

The lower gate electrode 120_1 may include at least one of a metal, a metal alloy, a conductive metal nitride, a metal silicide, a doped semiconductor material, a conductive metal oxide, and a conductive metal oxynitride. For example, the lower gate electrode 120_1 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), or vanadium (V), but aspects are not limited thereto. The conductive metal oxide and the conductive metal oxynitride may include an oxidized form of the material described above, but aspects are not limited thereto.

The lower gate dielectric 130 may be disposed between the lower gate electrode 120_1 and the lower insulating layer 110, between the lower gate electrode 120_1 and the lower channel pattern CP_B, and between the lower gate electrode 120_1 and the lower source/drain pattern 150. The lower gate dielectric 130 may surround the lower channel pattern CP_B. The lower gate dielectric 130 may extend along upper and lower surfaces of the lower channel pattern CP_B in the third direction D3. For example, the lower gate dielectric 130 may include at least one of silicon oxide, silicon oxynitride, and silicon nitride. The lower gate dielectric 130 may include multi-layers of silicon oxide and a high-k material. The high-k material may be a material having a higher dielectric constant than silicon oxide. For example, the high-k material may include at least one of hafnium oxide, hafnium silicon oxide, hafnium zirconium oxide, hafnium tantalum oxide, lanthanum oxide, zirconium oxide, and zirconium silicon oxide.

The upper active pattern AP_U may be disposed on the lower active pattern AP_B. The upper active pattern AP_U may extend in the first direction D1. The upper active pattern AP_U may be spaced apart from the lower active pattern AP_B in the first direction D1. The upper active pattern AP_U may be a multi-channel active pattern. The upper active pattern AP_U may include the upper channel pattern CP_U and an upper source/drain pattern 250.

The upper channel pattern CP_U may be disposed on the lower channel pattern CP_B. The upper channel pattern CP_U may be stacked on the lower channel pattern CP_B in the first direction D1. The upper channel pattern CP_U may be spaced apart from the lower channel pattern CP_B in the first direction D1. The upper channel pattern CP_U may be disposed to be spaced apart from another adjacent upper channel pattern CP_U in the second direction D2 that intersects with the first direction D1. In embodiments with a plurality of upper channel patterns CP_U, the upper channel patterns CP_U may be spaced apart from each other in the first direction D1. The upper channel pattern CP_U may have a nanosheet shape. The number of upper channel patterns CP_U may not be limited. For example, the number of upper channel patterns CP_U may be different from the number of lower channel patterns CP_B. In another example, the number of upper channel patterns CP_U may be the same as the number of lower channel patterns CP_B.

The upper channel pattern CP_U may include one of an elemental semiconductor material such as silicon (Si) or silicon germanium (SiGe), a group IV-IV compound semiconductor, or a group III-V compound semiconductor. For example, the group IV-IV compound semiconductor may be a binary compound or a ternary compound including at least two or more of carbon (C), silicon (Si), germanium (Ge), and tin (Sn). The group III-V compound semiconductor may be, for example, one of a binary compound, a ternary compound, or a quaternary compound formed by a combination of at least one of aluminum (Al), gallium (Ga) and indium (In) as a group III element and one of phosphorus (P), arsenic (As), and antimony (Sb) as a group V element.

The upper source/drain pattern 250 may be disposed on the lower source/drain pattern 150. The upper source/drain pattern 250 may be spaced apart from the lower source/drain pattern 150 in the first direction D1. The upper source/drain pattern 250 may be disposed on one side of the upper channel pattern CP_U. The upper source/drain pattern 250 may be disposed on one side of the upper gate structure 220. The upper source/drain pattern 250 may be connected to the upper channel pattern CP_U. A portion of a sidewall of the upper source/drain pattern 250 may be in contact with the upper channel pattern CP_U. Another portion of the sidewall of the upper source/drain pattern 250 may be in contact with the upper gate structure 220. The upper source/drain pattern 250 may connect the upper channel patterns CP_U that are stacked in the first direction D1. The upper source/drain patterns 250 may be disposed between a plurality of adjacent upper channel patterns CP_U that are spaced apart from each other in the second direction D2 that intersects with the first direction D1.

The upper source/drain pattern 250 may be disposed on one side of the upper gate structure 220. The upper source/drain pattern 250 may be disposed between a plurality of upper gate structures 220 adjacent to each other in the second direction D2 that intersects with the first direction D1.

The upper source/drain pattern 250 may include, for example a first upper source/drain pattern 250_1 and a second upper source/drain pattern 250_2. The first upper source/drain pattern 250_1 and the second upper source/drain pattern 250_2 may be disposed on one side of the upper gate structure 220. The first upper source/drain pattern 250_1 and the second upper source/drain pattern 250_2 may be spaced apart from each other in the second direction D2. Each of the first upper source/drain pattern 250_1 and the second upper source/drain pattern 250_2 may be disposed between a plurality of upper channel patterns CP_U spaced apart from each other in the second direction D2. Alternatively, each of the first upper source/drain pattern 250_1 and the second upper source/drain pattern 250_2 may be disposed between the plurality of upper gate structures 220 spaced apart from each other in the second direction D2. For example, the first upper source/drain pattern 250_1 may be disposed on one side of the upper gate structure 220 in the second direction D2. For example, the second upper source/drain pattern 250_2 may be disposed on the other side of the upper gate structure 220 in the second direction D2. The first upper source/drain pattern 250_1 may be disposed on the first lower source/drain pattern 150_1, for example on the same side of the semiconductor device 10 in the second direction D2. The first upper source/drain pattern 250_1 may be spaced apart from the first lower source/drain pattern 150_1 in the first direction D1. The second upper source/drain pattern 250_2 may be disposed on the second lower source/drain pattern 150_2, for example on the same side of the semiconductor device 10 in the second direction D2. The second upper source/drain pattern 250_2 may be spaced apart from the second lower source/drain pattern 150_2 in the first direction D1.

The upper source/drain pattern 250 may be a semiconductor material. For example, the upper source/drain pattern 250 may include an element semiconductor material such as silicon (Si) or germanium (Ge). For example, the upper source/drain pattern 250 may include a binary compound or a ternary compound including at least two or more of carbon (C), silicon (Si), germanium (Ge), and tin (Sn), or a compound of these doped with a group IV element. For example, the upper source/drain pattern 250 may include silicon (Si), silicon-germanium (SiGe), germanium (Ge), or silicon carbide (SiC), etc., but is not limited thereto.

The upper source/drain pattern 250 may include impurities doped into a semiconductor material. The doped impurities may include at least one of boron (B), phosphorus (P), carbon (C), arsenic (As), antimony (Sb), bismuth (Bi), and oxygen (O), but aspects are not limited thereto.

Although the upper source/drain pattern 250 is illustrated as a single layer, this is only for convenience of description and aspects are not limited thereto. In some aspects, the upper source/drain pattern 250 may include a plurality of layers including different materials. In another aspect, the upper source/drain pattern 250 may include a plurality of layers having the same material and may include a plurality of layers having different concentrations of constituent materials.

The upper gate structure 220 may be disposed on the lower gate structure 120. The upper gate structure 220 may surround the upper channel pattern CP_U. The upper gate structure 220 may be spaced apart from the lower gate structure 120 in the first direction D1. The upper gate structure 220 may include upper gate electrodes 220_1 and 220_2 and an upper gate dielectric 230. The upper gate electrodes 220_1 and 220_2 may be disposed on the lower gate electrode 120_1 and may extend in the third direction D3. The upper gate electrodes 220_1 and 220_2 may surround the upper channel pattern CP_U. For example, the upper gate electrodes 220_1 and 220_2 may surround an upper surface, a lower surface, and both side surfaces of the upper channel pattern CP_U. The upper and lower surfaces of the upper channel pattern CP_U may refer to surfaces that intersect with the first direction D1, and both side surfaces of the upper channel pattern CP_U may refer to surfaces that intersect with the third direction D3. Among the upper gate electrodes 220_1 and 220_2, the upper gate electrode disposed on the upper channel pattern CP_U disposed at the top in the first direction D1, may be referred to as a first upper gate electrode 220_1. In addition, the upper gate electrode at least partially alternately stacked with the upper channel pattern CP_U may be referred to as a second upper gate electrode 220_2.

The upper gate electrodes 220_1 and 220_2 may include at least one of a metal, a metal alloy, a conductive metal nitride, a metal silicide, a doped semiconductor material, a conductive metal oxide, and a conductive metal oxynitride. For example, the upper gate electrodes 220_1 and 220_2 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), or vanadium (V). However, aspects are not limited to the above. The conductive metal oxide and the conductive metal oxynitride may include an oxidized form of the material described above, but is not limited thereto.

The upper gate dielectric 230 may be disposed between the upper gate electrodes 220_1 and 220_2 and the upper channel pattern CP_U, and between the upper gate electrodes 220_1 and 220_2 and the upper source/drain pattern 250. In addition, the upper gate dielectric 230 may be disposed between the upper gate electrodes 220_1 and 220_2 and a first interlayer dielectric ILD_1. The upper gate dielectric 230 may surround the upper channel pattern CP_U. The upper gate dielectric 230 may extend along the upper and lower surfaces of the upper channel pattern CP_U in the third direction D3. For example, the upper gate dielectric 230 may include at least one of silicon oxide, silicon oxynitride, and silicon nitride. The upper gate dielectric 230 may include multi-layers of silicon oxide and high-k material. The high-k material may be a material having a higher dielectric constant than silicon oxide. For example, the high-k material may include at least one of hafnium oxide, hafnium silicon oxide, hafnium zirconium oxide, hafnium tantalum oxide, lanthanum oxide, zirconium oxide, and zirconium silicon oxide.

The first spacer 255 may be disposed on the first upper source/drain pattern 250_1. The first spacer 255 may extend in the third direction D3. The first spacer 255 may be spaced apart from the first upper source/drain pattern 250_1 in the first direction D1. For example, the first spacer 255 may include at least one of silicon nitride (SiN), silicon oxide (SiO), silicon oxynitride (SiON), silicon oxycarbonitride (SiOCN), silicon boron nitride (SiBN), silicon oxide boron nitride (SiOBN), and silicon oxide carbonate (SiOC).

The source/drain contacts SC_1, SC_2, and SC_3 may be connected to the lower source/drain pattern 150 and/or the upper source/drain pattern 250. Specifically, the source/drain contacts SC_1, SC_2, and SC_3 may be electrically connected to the lower source/drain pattern 150 and/or the upper source/drain pattern 250. The source/drain contacts SC_1, SC_2, and SC_3 may include the first source/drain contact SC_1, the second source/drain contact SC_2, and a third source/drain contact SC_3.

The first source/drain contact SC_1 may be disposed on the first lower source/drain pattern 150_1. The first source/drain contact SC_1 may extend along a side surface of the first spacer 255 in the first direction D1. For example, the first spacer 255 may overlap with at least a portion of the first source/drain contact SC_1 in the second direction D2. The first source/drain contact SC_1 may extend along the side surface of the first spacer 255, extend through the first spacer 255 and the first upper source/drain pattern 250_1, and be connected to the first upper source/drain pattern 250_1 and the first lower source/drain pattern 150_1. As illustrated, e.g., in FIGS. 2 and 4, the first source/drain contact SC_1 may be in contact with an upper surface of the first lower source/drain pattern 150_1. Alternatively, as illustrated, e.g., in FIGS. 3 and 5, the first source/drain contact SC_1 may extend in the first direction through at least a portion of the first lower source/drain pattern 150_1. Specifically, at least a portion of the first source/drain contact SC_1 may overlap with the first lower source/drain pattern 150_1 in the second direction D2 that intersects with the first direction D1. Because the first source/drain contact SC_1 is connected to the first upper source/drain pattern 250_1 and the first lower source/drain pattern 150_1, an additional source/drain contact for connecting the first lower source/drain pattern 150_1 to an external device may be omitted.

The second source/drain contact SC_2 may be disposed on the second upper source/drain pattern 250_2. The second source/drain contact SC_2 may extend in the first direction D1 and be connected to the second upper source/drain pattern 250_2. As illustrated, e.g., in FIGS. 4 and 5, the second source/drain contact SC_2 may be in contact with an upper surface of the second upper source/drain pattern 250_2. Alternatively, as illustrated, e.g., in FIGS. 2 and 3, the second source/drain contact SC_2 may extend in the first direction through at least a portion of the second upper source/drain pattern 250_2. Specifically, at least a portion of the second source/drain contact SC_2 may overlap with the second upper source/drain pattern 250_2 in the second direction D2 that intersects with the first direction D1.

The third source/drain contact SC_3 may extend in the first direction D1 and through the lower insulating layer 110. The third source/drain contact SC_3 may be connected to the second lower source/drain pattern 150_2. The third source/drain contact SC_3 may be in contact with a lower surface of the second lower source/drain pattern 150_2.

The source/drain contacts SC_1, SC_2, and SC_3 may each include a corresponding conductive liner layer 290 and a filling layer 295. Each conductive liner layer 290 may be conformally disposed along side and lower surfaces of the corresponding source/drain contact SC_1, SC_2, and SC_3, and each filling layer 295 may be disposed on the corresponding conductive liner layer 290 to fill the interior of the corresponding source/drain contact SC_1, SC_2, and SC_3. Therefore, each conductive liner layer 290 may surround a corresponding filling layer 295. The filling layer 295 may include at least one of a metal, a metal nitride, a metal carbonitride, a two-dimensional (2D) material, and a conductive semiconductor material. The conductive liner layer 290 may include a metal film/metal nitride film. The metal layer may include at least one of titanium, tantalum, tungsten, nickel, cobalt, and platinum. The metal nitride film may include at least one of titanium nitride (TiN), tantalum nitride (TaN), tungsten nitride (WN), nickel nitride (NiN), cobalt nitride (CoN), and platinum nitride (PtN). The conductive liner layer 290 may adjust contact resistance between the filling layer 295 and the upper source/drain pattern 250 and the lower source/drain pattern 150.

The semiconductor device 10 may further include interlayer dielectrics ILD_1, ILD_2, and ILD_3. For example, the interlayer dielectrics ILD_1, ILD_2, and ILD_3 may include at least one of silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, and mesoporous silica, or a combination of two or more thereof, but is not limited thereto. For example, the interlayer dielectrics ILD_1, ILD_2, and ILD_3 may include a material different from that of the first spacer 255. The interlayer dielectrics ILD_1, ILD_2, and ILD_3 may include a first interlayer dielectric ILD_1, a second interlayer dielectric ILD_2, and a third interlayer dielectric ILD_3.

The first interlayer dielectric ILD_1 may be disposed on the lower channel pattern CP_B and the lower gate structure 120. The first interlayer dielectric ILD_1 may be disposed on the lower source/drain pattern 150. The first interlayer dielectric ILD_1 may extend in the second and/or third directions D2 and D3. The first interlayer dielectric ILD_1 may be in contact with the lower gate structure 120. The first interlayer dielectric ILD_1 may be in contact with the lower source/drain pattern 150. The first source/drain contact SC_1 may extend in the first direction through the first interlayer dielectric ILD_1 and connected to the first lower source/drain pattern 150_1.

The second interlayer dielectric ILD_2 may be disposed on the first interlayer dielectric ILD_1. The second interlayer dielectric ILD_2 may be disposed on the lower surface of the upper source/drain pattern 250. The second interlayer dielectric ILD_2 may be in contact with the upper source/drain pattern 250. The first source/drain contact SC_1 may extend in the first direction through the second interlayer dielectric ILD_2 and connected to the first lower source/drain pattern 150_1.

The third interlayer dielectric ILD_3 may be disposed on the second upper source/drain pattern 250_2. The second source/drain contact SC_2 may extend in the first direction through the third interlayer dielectric ILD_3 and be connected to the second upper source/drain pattern 250_2. For example,, the third interlayer dielectric ILD_3 may extend along the side surface of the second source/drain contact SC_2 in the first direction D1. Alternatively, the third interlayer dielectric ILD_3 may be disposed on the sidewall of the second source/drain contact SC_2. A thickness of the third interlayer dielectric ILD_3 in the second direction D2 may be different from a thickness of the first spacer 255 in the second direction D2. For example, the thickness of the third interlayer dielectric ILD_3 in the second direction D2 may be less than the thickness of the first spacer 255 in the second direction D2. For example, the thickness of the third interlayer dielectric ILD_3 in the second direction D2 may be greater than the thickness of the first spacer 255 in the second direction D2. However, aspects are not limited to the above, and the thickness of the third interlayer dielectric ILD_3 in the second direction D2 may be the same as the thickness of the first spacer 255 in the second direction D2. For example, the third interlayer dielectric ILD_3 may include an insulating material different from that of the first spacer 255. However, aspects are not limited to the above, and the third interlayer dielectric ILD_3 may be the same insulating material as the first spacer 255.

The semiconductor device 10 may further include a second spacer 265. The second spacer 265 may be disposed on a side surface of the upper gate structure 220. Specifically, the second spacer 265 may be disposed on the side surface of the first upper gate electrode 220_1. For example, the second spacer 265 may extend along a side surface of the first upper gate electrode 220_1. For example, the second spacer 265 may include at least one of silicon nitride (SiN), silicon nitride oxide (SiON), silicon oxide (SiO₂), silicon carbonate nitride (SiOCN), silicon boron nitride (SiBN), silicon oxide boron nitride (SiOBN), or silicon oxide carbonate (SiOC). The second spacer 265 may include a single layer or a plurality of layers. The second spacer 265 may be a gate spacer.

The semiconductor device 10 may further include an etch stop layer 270. The etch stop layer 270 may be disposed between the first spacer 255 and the second spacer 265. At least a portion of the etch stop layer 270 may overlap with the first spacer 255 in the first direction D1. At least a portion of the etch stop layer 270 may overlap with the first spacer 255 in the second direction D2. The etch stop layer 270 may extend along a side surface of the second spacer 265. For example, the etch stop layer 270 may include at least one of silicon nitride (SiN), silicon oxide (SiO), silicon oxynitride (SiON), silicon oxycarbonitride (SiOCN), silicon boron nitride (SiBN), silicon oxide boron nitride (SiOBN), and silicon oxide carbonate (SiOC).

The etch stop layer 270 and the first spacer 255 may be the same insulating material. In this case, a boundary between the etch stop layer 270 and the first spacer 255 may not be distinguishable. If the etch stop layer 270 and the first spacer 255 are formed of the same material, the etch stop layer 270 and the first spacer 255 may be collectively referred to as the etch stop layer 270. Accordingly, the etch stop layer 270 formed on the upper side surface of the first source/drain contact SC_1 may be thicker than the etch stop layer 270 formed on the side surface of the second source/drain contact SC_2 in the second direction D2. As another example, the etch stop layer 270 and the first spacer 255 may be different insulating materials from each other.

The thickness of the first spacer 255 in the second direction D2 may be greater than a thickness of the etch stop layer 270 in the second direction D2. The etch stop layer 270 and the first spacer 255 may have the same thickness in the second direction D2. The thickness of the first spacer 255 in the second direction D2 may be greater than the thickness of the third interlayer dielectric ILD_3 in the second direction D2. A distance between the second source/drain contact SC_2 and the etch stop layer 270 on the second upper source/drain pattern 250_2 may be less than a distance between the first source/drain contact SC_1 and the etch stop layer 270 on the first upper source/drain pattern 250_1.

The semiconductor device 10 may further include a gate capping pattern 280. The gate capping pattern 280 may be disposed on the first upper gate electrode 220_1 and the upper gate dielectric 230. The gate capping pattern 280 may cover an upper surface of the first upper gate electrode 220_1. For example, the gate capping pattern 280 may include at least one of silicon nitride (SiN), silicon oxynitride (SiON), silicon carbonitride (SiCN), and silicon oxycarbonitride (SiOCN).

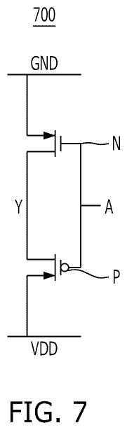

FIG. 7 is an example circuit diagram provided to explain a semiconductor device according to some aspects. Referring to FIG. 7, the circuit diagram 700 may include an inverter circuit connected in series between a power source VDD and a ground GND. The inverter circuit may be a component metal-oxide-semiconductor (CMOS) inverter. The CMOS inverter may include PMOS (P) and NMOS (N) connected in series between the power source VDD and the ground GND. For example, the PMOS (P) at the top may be connected between the power source VDD and the output Y. For example, the NMOS (N) at the bottom may be connected between the ground GND and the output Y. The PMOS (P) at the top may be a P-channel MOSFET. The NMOS (N) at the bottom may be an N-channel MOSFET. The circuit diagram 700 may be implemented by the semiconductor device 10 according to some aspects illustrated in FIGS. 1 to 6. A source/drain contact, which extends in the first direction through the upper source/drain pattern and electrically connected to the upper source/drain pattern and the lower source/drain pattern, may be implemented in some areas of the semiconductor device 10 such that various integrated circuits can be implemented without an additional wiring process. As a result, the integration density and electrical characteristics of the semiconductor device can be improved. For example, in addition to the circuit diagram 700 illustrated in FIG. 7, various electronic circuits may be implemented through a simple wiring process using the semiconductor device 10 according to some aspects illustrated in FIGS. 1 to 6.

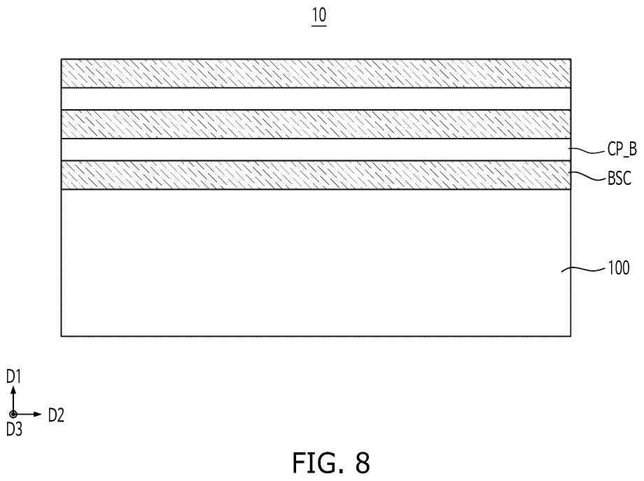

FIGS. 8 to 19 are diagrams illustrating intermediate stages of a method for manufacturing a semiconductor device according to some aspects. In the following descriptions of certain components, detailed description of the same components already described in FIGS. 1 to 7 may be omitted. Referring to FIG. 8, according to a method for manufacturing the semiconductor device 10 according to some aspects, a lower sacrificial layer BSC and the lower channel pattern CP_B may be alternately stacked on a substrate 100. The substrate 100 may include any one of silicon (Si), germanium (Ge), or silicon-germanium (SiGe). For example, the substrate 100 may be a single crystal silicon wafer. The lower sacrificial layer BSC may be silicon germanium (SiGe), and the lower channel pattern CP_B may be silicon (Si). The lower sacrificial layer BSC may be disposed on top of the stack structure. However, aspects are not limited to the above.

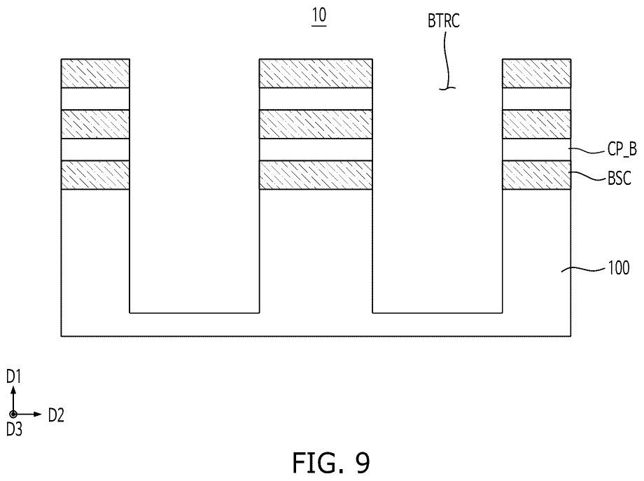

Referring to FIG. 9, a lower trench BTRC may be formed by etching portions of the substrate 100, the lower sacrificial layer BSC, and the lower channel pattern CP_B. One or more lower trenches BTRC may be formed on the substrate. The lower trenches BTRC may be formed by dividing through processes such as lithography, masking, and top-down etching based on a hardmask pattern disposed on top of the structure in which the lower sacrificial layer BSC and the lower channel pattern CP_B are alternately stacked. The etching process may be performed through an etching recipe having a high etching rate for silicon and silicon germanium. The lower trenches BTRC may extend into the substrate below the upper surface level of the substrate 100. The lower trenches BTRC may be formed to be spaced apart from each other in the second direction D2. The second direction D2 may be a direction that intersects with the first direction D1. A profile by etching may be formed on the lower sacrificial layer BSC and the lower channel pattern CP_B. Sidewalls of the lower sacrificial layer BSC and the lower channel pattern CP_B may be inclined such that the sidewalls may be closer to each other in the second direction D2 toward the substrate 100 in the first direction D1. The lower trench BTRC may have a shape that is narrower toward the interior of the substrate 100.

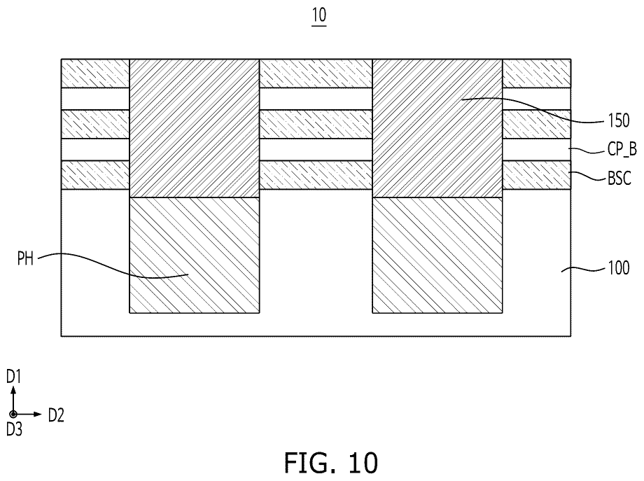

Referring to FIG. 10, the lower trench (e.g., the lower trench BTRC of FIG. 9) may be filled sequentially with a placeholder PH and the lower source/drain pattern 150. The placeholder PH may extend up to the upper surface of the substrate 100 in the first direction D1. The upper surface of the placeholder PH may be formed at the same level as the upper surface of the substrate 100. The placeholder PH may be formed by filling a lower portion of the lower trench of the substrate 100 with a material such as silicon germanium (SiGe). For example, the placeholder PH may be performed through at least one of Chemical Vapor Deposition (CVD), Plasma Enhanced CVD (PECVD), Physical Vapor Deposition (PVD), and Atomic Layer Deposition (ALD), and may be planarized by Chemical Mechanical Planarization (CMP).

The lower source/drain pattern 150 may be formed on the placeholder PH. The lower source/drain pattern 150 may be formed by epitaxially growing silicon, etc. included in the lower sacrificial layer BSC and the lower channel pattern CP_B exposed by the lower trench. The lower source/drain pattern 150 may be formed such that a lower surface thereof is in contact with an upper surface of the placeholder PH. The lower source/drain pattern 150 may be formed at the same level as the upper surfaces of the adjacent lower sacrificial layer BSC and lower channel pattern CP_B. To this end, CMP may be performed on the upper surface of the lower source/drain pattern 150.

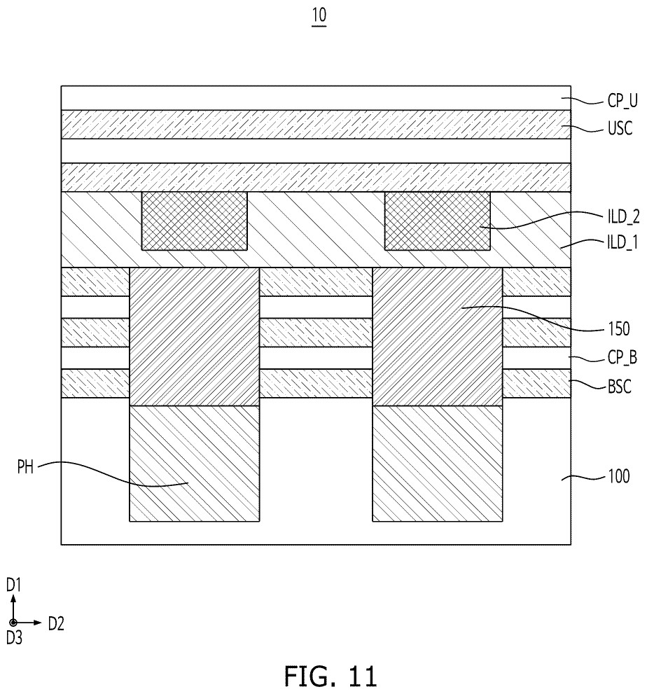

Referring to FIG. 11, the first interlayer dielectric ILD_1, the second interlayer dielectric ILD_2, an upper sacrificial layer USC, and the upper channel pattern CP_U may be formed on the lower sacrificial layer BSC, the lower channel pattern CP_B, and the lower source/drain pattern 150. A lower surface of the first interlayer dielectric ILD_1 may be in contact with upper surfaces of the lower sacrificial layer BSC, the lower channel pattern CP_B, and the lower source/drain pattern 150. The second interlayer dielectric ILD_2 may be formed by etching a portion of the first interlayer dielectric ILD_1. The second interlayer dielectric ILD_2 may be the same material as the first interlayer dielectric ILD_1. Alternatively, the second interlayer dielectric ILD_2 may be a material different from that of the first interlayer dielectric ILD_1. The second interlayer dielectric ILD_2 may be formed to overlap with the placeholder PH and/or the lower source/drain pattern 150 in the first direction D1. The second interlayer dielectric ILD_2 may be formed such that a lower surface of the second interlayer dielectric ILD_2 is in contact with the first interlayer dielectric ILD_1. The first and second interlayer dielectrics ILD_1 and ILD_2 may be formed by at least one of CVD, PECVD, and PVD.

The upper sacrificial layer USC and the upper channel pattern CP_U may be alternately stacked on the first and second interlayer dielectrics ILD_1 and ILD_2. The upper sacrificial layer USC may include silicon germanium (SiGe), and the upper channel pattern CP_U may include silicon (Si). The upper channel pattern CP_U may be disposed on top of the stack structure. However, aspects are not limited to the above. The number of upper sacrificial layers USC and upper channel patterns CP_U formed may be the same as the number of lower sacrificial layers BSC and lower channel patterns CP_B formed. Alternatively, the number of upper sacrificial layers USC and upper channel patterns CP_U formed may be different from the number of lower sacrificial layers BSC and lower channel patterns CP_B formed. Aspects are not limited to the illustrations, and each stack structure may include any of the stack structures herein.

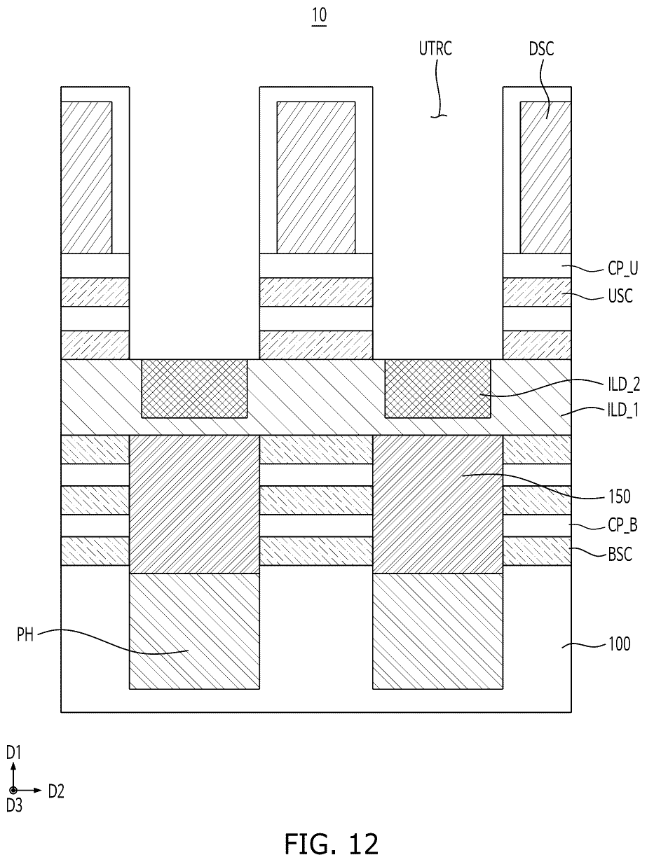

Referring to FIG. 12, a gate sacrificial pattern DSC may be formed on the upper sacrificial layer USC and the upper channel pattern CP_U. The gate sacrificial pattern DSC may have a line shape extending in the second direction D2. A hard mask pattern may be formed on the gate sacrificial pattern DSC. An upper trench UTRC may be formed by etching portions of the upper sacrificial layer USC, the upper channel pattern CP_U, and the gate sacrificial pattern DSC. One or more upper trenches UTRC may be formed on the substrate. The upper trenches UTRC may be formed to overlap with the placeholder PH, the lower source/drain pattern 150, and the second interlayer dielectric ILD_2 in the first direction D1. The upper trench UTRC may be formed by dividing through processes such as lithography, masking, and top-down etching based on a hardmask pattern disposed on top of the structure in which the upper sacrificial layer USC and the upper channel pattern CP_U are alternately stacked. The etching process may be performed through an etching recipe having a high etching rate for silicon and silicon germanium. A profile by etching may be formed on the upper sacrificial layer USC and the upper channel pattern CP_U. Sidewalls of the upper sacrificial layer USC and the upper channel pattern CP_U may be inclined such that the sidewalls may be closer to each other in the second direction D2 toward the substrate 100 in the first direction D1. The upper trench UTRC may have a shape that is narrower toward the substrate 100 in the first direction D1.

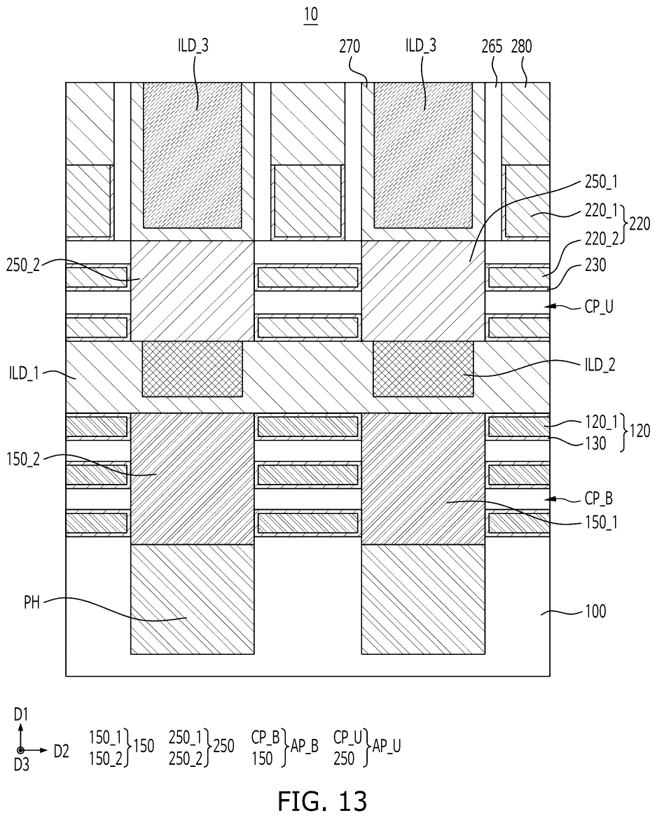

Referring to FIG. 13, the upper source/drain pattern 250 may be filled in the upper trench. The upper source/drain pattern 250 may extend in the first direction D1. The upper source/drain pattern 250 may be formed at the same level as upper surfaces of the upper sacrificial layer USC and the upper channel pattern CP_U. The upper source/drain pattern 250 may be formed by epitaxially growing silicon, etc. included in the upper sacrificial layer USC and the upper channel pattern CP_U exposed by the upper trench.

Through a replacement process, the sacrificial layers may be removed and the gate electrodes 120_1, 220_1, and 220_2 may be formed. The gate capping pattern 280 may be formed on the upper gate electrodes 220_1 and 220_2, and the second spacer 265, the etch stop layer 270, and the third interlayer dielectric ILD_3 may be formed on a side surface of the gate capping pattern 280. The second spacer 265 may be a gate spacer.

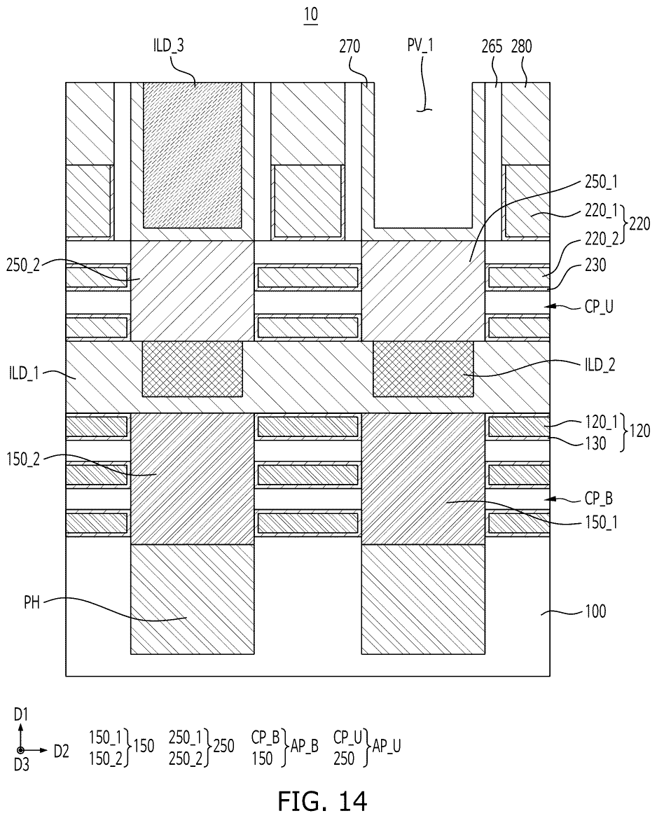

Referring to FIG. 14, a portion of the third interlayer dielectric ILD_3 may be removed. For example, the third interlayer dielectric ILD_3 disposed on the first lower source/drain pattern 150_1 may be selectively removed. The third interlayer dielectric ILD_3 may be removed by a dry or wet etching process. Accordingly, the etch stop layer 270 may be exposed to the outside, and a first through via PV_1 may be formed on the first lower source/drain pattern 150_1.

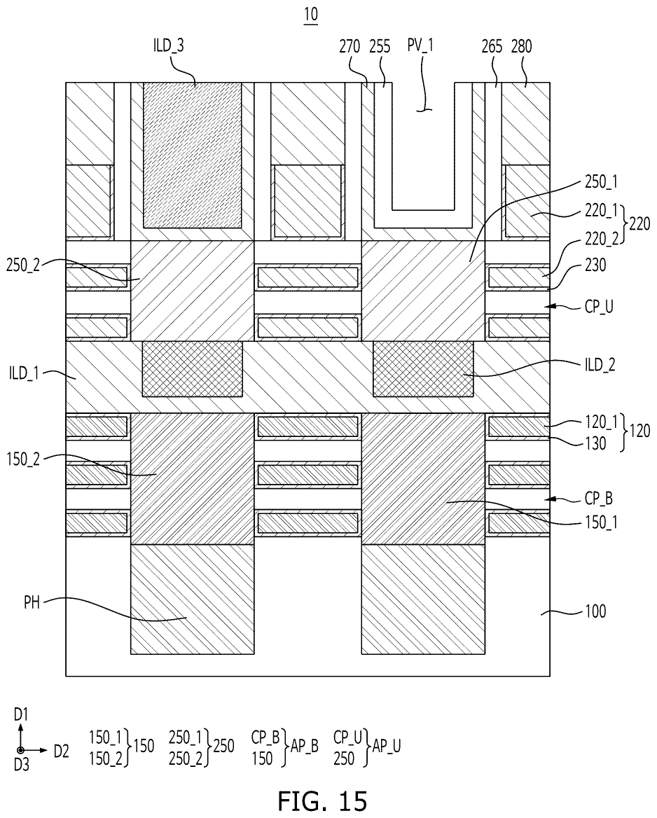

Referring to FIG. 15, the first spacer 255 may be formed on the etch stop layer 270. The first spacer 255 may be formed along a sidewall of the etch stop layer 270. The etch stop layer 270 may be formed to cover a first spacer 255. The first spacer 255 may be formed to partially fill the first through via PV_1. The first spacer 255 may be formed by performing a selective epitaxial growth (SEG) process using the exposed etch stop layer 270 as a seed layer. The first spacer 255 may be the same insulating material as the etch stop layer 270. Alternatively, the first spacer 255 may be an insulating material different from that of the etch stop layer 270. However, aspects are not limited to the above, and the first spacer 255 may be formed through various deposition processes such as CVD, PECVD, PVD, or ALD.

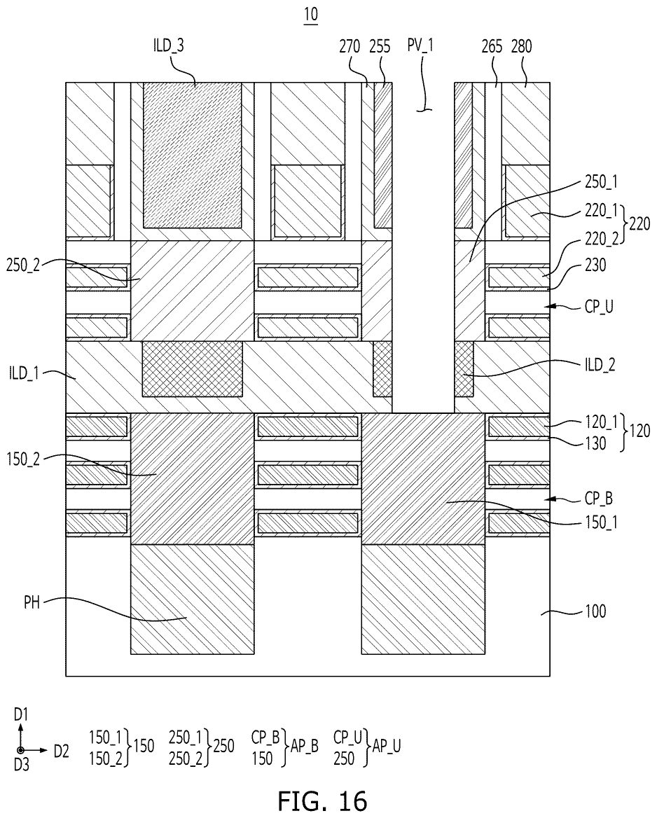

Referring to FIG. 16, the first through via PV_1 may extend in the first direction to expose a portion of the upper surface of the first lower source/drain pattern 150_1. Any etching process such as dry etching, and wet etching may be performed to extend the first through via PV_1. Accordingly, a profile by etching of the first through via PV_1 may emerge. For example, the first through via PV_1 may have a shape that is narrower toward the substrate 100 in the first direction D1.

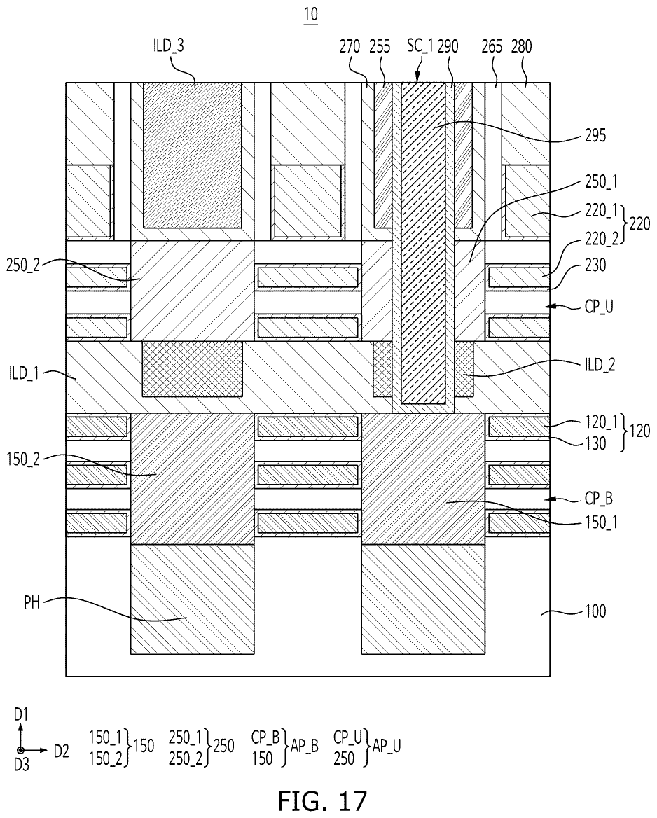

Referring to FIG. 17, the first source/drain contact SC_1 may be filled in the first through via. The first source/drain contact SC_1 may be formed by filling a conductive material through at least one of PVD, CVD, PECVD, and ALD. For example, the first source/drain contact SC_1 may include the conductive liner layer 290 and the filling layer 295. The conductive liner layer 290 may be conformally disposed along the side surface and the lower surface of the first source/drain contact SC_1, and the filling layer 295 may be disposed on the conductive liner layer 290 to fill the interior of the first source/drain contact SC_1. Therefore, the conductive liner layer 290 may surround the filling layer 295. The first source/drain contact SC_1 may be disposed on the first lower source/drain pattern 150_1. The first source/drain contact SC_1 may extend along the side surface of the first spacer 255 in the first direction D1. For example, the first spacer 255 may overlap with at least a portion of the first source/drain contact SC_1 in the second direction D2. The first source/drain contact SC_1 may extend in the first direction through the first spacer 255 and the first upper source/drain pattern 250_1 and connected to the first upper source/drain pattern 250_1 and the first lower source/drain pattern 150_1. The first source/drain contact SC_1 may be in contact with the upper surface of the first lower source/drain pattern 150_1. Alternatively, the first source/drain contact SC_1 may extend in the first direction through at least a portion of the first lower source/drain pattern 150_1. Specifically, at least a portion of the first source/drain contact SC_1 may overlap with the first lower source/drain pattern 150_1 in the second direction D2 that intersects with the first direction D1.

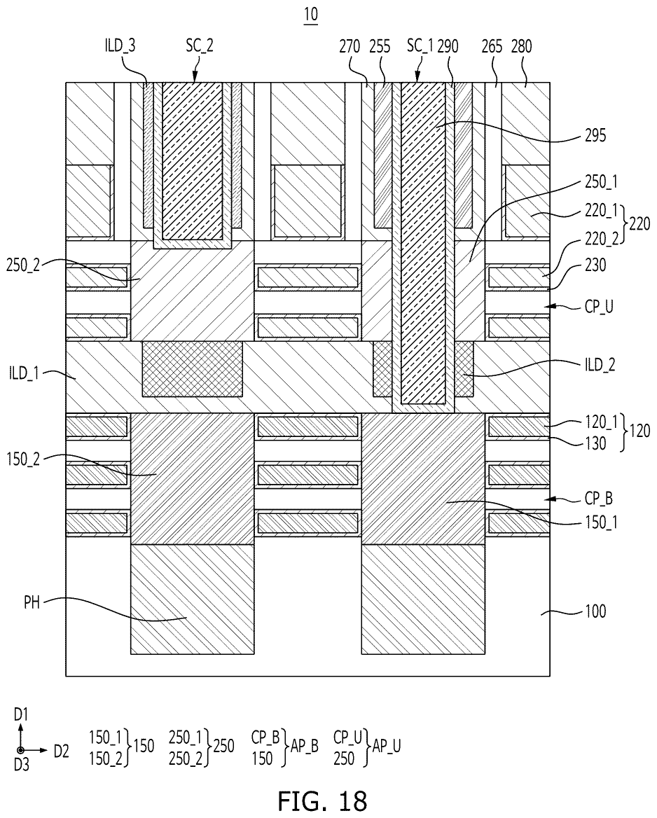

Referring to FIG. 18, the second source/drain contact SC_2 may be formed on the second upper source/drain pattern 250_2. The second source/drain contact SC_2 may be formed by filling a conductive material through at least one of PVD, CVD, PECVD, and ALD,. For example, the second source/drain contact SC_2 may include the conductive liner layer 290 and the filling layer 295. The second source/drain contact SC_2 may be connected to the second upper source/drain pattern 250_2. The second source/drain contact SC_2 may be in contact with the upper surface of the second upper source/drain pattern 250_2. At least a portion of the second source/drain contact SC_2 may overlap with the second upper source/drain pattern 250_2 in the second direction D2. Although not illustrated, before the operation of forming the second source/drain contact SC_2, the second through via may be formed on the second upper source/drain pattern 250_2 through dry or wet etching, etc.

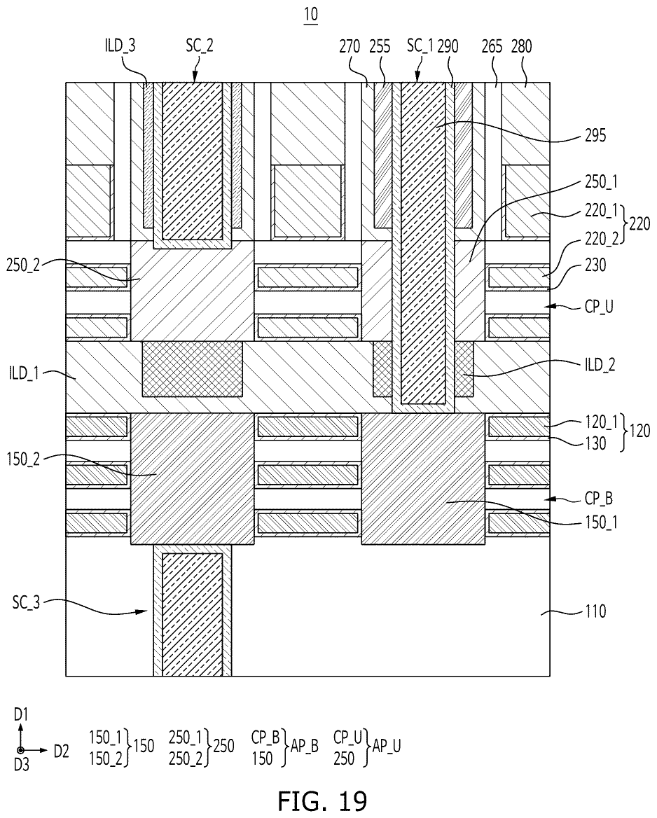

Referring to FIG. 19, the lower insulating layer 110 and the third source/drain contact SC_3 may be formed on the lower surface of the second lower source/drain pattern 150_2. For example, the third source/drain contact SC_3 may include the conductive liner layer 290 and the filling layer 295. The lower insulating layer 110 and the third source/drain contact SC_3 may be formed by removing the substrate 100 and the placeholder PH illustrated in FIG. 18 through a backside process of flipping the semiconductor device 10. The substrate 100 and the placeholder PH illustrated in FIG. 18 may be removed by a dry or wet etching process, etc. FIG. 19 illustrates that the third source/drain contact SC_3 is formed only on the lower surface of the second lower source/drain pattern 150_2 after removing, for example completely removing, the placeholder PH disposed on the lower surface of the lower source/drain pattern 150, but aspects are not limited thereto. The third source/drain contact SC_3 may be formed after removing only a portion of the placeholder PH disposed on the lower surface of the lower source/drain pattern 150, for example, in a region from which the placeholder PH has been removed. For example, the third source/drain contact SC_3 may be formed after removing only the placeholder PH disposed on the lower surface of the second lower source/drain pattern 150_2, while not removing, for example, maintaining the placeholder PH disposed on the lower surface of the first lower source/drain pattern 150_1. The lower insulating layer 110 may extend in the second direction D2. The lower insulating layer 110 may be formed by filling an insulating material through at least one of CVD, PECVD, and ALD. The lower insulating layer 110 may be in contact with the lower gate structure 120 and the lower source/drain pattern 150. The conductive liner layer 290 may be further formed on the third source/drain contact SC_3. The third source/drain contact SC_3 may be connected to the second lower source/drain pattern 150_2. Before the operation of forming the third source/drain contact SC_3, a third through via may be formed in the lower insulating layer 110 through dry or wet etching, etc. The third through via may overlap with the second lower source/drain pattern 150_2 in the first direction D1.

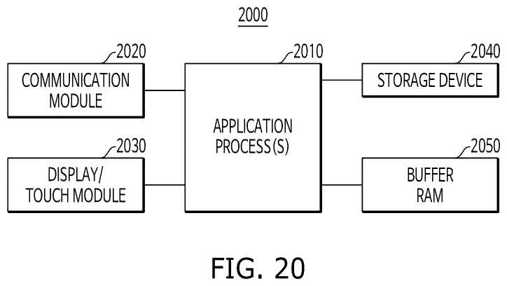

FIG. 20 is a schematic block diagram illustrating an electronic device including a semiconductor device according to some aspects. Referring to FIG. 20, an electronic device 2000 may include at least one application processor 2010, a communication module 2020, a display/touch module 2030, a storage device 2040, and a buffer random access memory (RAM) 2050. According to aspects, the electronic device 2000 may be a mobile device such as a smartphone or a tablet computer, but is not limited thereto.

The application processor 2010 may control operations of the electronic device 2000. The communication module 2020 may be implemented to perform wireless or wired communication with an external device. The display/touch module 2030 may be implemented to display data processed by the application processor 2010 or to receive data through a touch panel. The storage device 2040 may be implemented to store user data. The storage device 2040 may be an embedded multimedia card (eMMC), a solid state drive (SSD), a universal flash storage (UFS) device, etc., but is not limited thereto. The storage device 2040 may perform caching of mapping data and user data as described herein.

The buffer RAM 2050 may temporarily store data used in processing the operations of the electronic device 2000. For example, the buffer RAM 2050 may be a volatile memory such as a Double Data Rate Synchronous Dynamic Random Access Memory (DDR SDRAM), a Low-Power Power Double Data Rate (LPDDR) SDRAM, a Graphics Double Data Rate (GDDR) SDRAM, a Rambus Dynamic Random Access Memory (RDRAM), and FeRAM (Ferroelectric RAM).

Although not illustrated in FIG. 20, the electronic device 2000 may further include at least one sensor such as an image sensor. At least one component of the electronic device 2000 may include the semiconductor device 10 according to the aspects illustrated in FIGS. 1 to 6.

Although the present disclosure has been described herein by way of certain aspects and drawings, the present disclosure is not limited thereto, and that various changes and modifications can be made within the equivalent scope of the technical idea of the present disclosure and the claims by those of ordinary skill in the art.

1. A semiconductor device, comprising:
a lower insulating layer;
a lower channel pattern stacked on the lower insulating layer in a first direction;
an upper channel pattern spaced apart from the lower channel pattern in the first direction;
a lower gate structure surrounding the lower channel pattern;
an upper gate structure surrounding the upper channel pattern;
a first lower source/drain pattern disposed on a first side of the lower gate structure in a second direction that intersects the first direction;
a first upper source/drain pattern spaced apart from the first lower source/drain pattern in the first direction and disposed on a first side of the upper gate structure in the second direction;
a first spacer disposed on the first upper source/drain pattern;
a first source/drain contact extending along a first side surface of the first spacer in the first direction, extending through the first spacer and the first upper source/drain pattern, and connected to the first upper source/drain pattern and the first lower source/drain pattern;
a second lower source/drain pattern disposed on a second side of the lower gate structure in the second direction;
a second upper source/drain pattern spaced apart from the second lower source/drain pattern in the first direction and disposed on a second side of the upper gate structure in the second direction;
a first interlayer dielectric disposed on the second upper source/drain pattern; and
a second source/drain contact extending along a side surface of the first interlayer dielectric in the first direction, extending through the first interlayer dielectric, and connected to the second upper source/drain pattern, wherein
a thickness of the first spacer in a second direction is different from a thickness of the first interlayer dielectric in the second direction;
the first side of the lower gate structure and the first side of the upper gate structure face a first side of the semiconductor device in the second direction; and
the second side of the lower gate structure and the second side of the upper gate structure face a second side of the semiconductor device opposite the first side of the semiconductor device in the second direction.

2. The semiconductor device according to claim 1, wherein the first source/drain contact is in contact with an upper surface of the first lower source/drain pattern.

3. The semiconductor device according to claim 1, wherein the first source/drain contact overlaps with at least a portion of the first lower source/drain pattern in the second direction.

4. The semiconductor device according to claim 1, further comprising:
a second spacer disposed on a side surface of the upper gate structure; and
an etch stop layer disposed between the first spacer and the second spacer, wherein
the etch stop layer contacts a second side surface of the first spacer opposite the first side surface of the first spacer, and extends along a bottom surface of the first spacer.

5. The semiconductor device according to claim 4, wherein the etch stop layer and the first spacer include the same insulating material.

6. The semiconductor device according to claim 4, wherein a thickness of the first spacer in the second direction is greater than a thickness of the etch stop layer in the second direction at a position in the first direction where the etch stop layer contacts the second side surface of the first spacer.

7. The semiconductor device according to claim 1, further comprising a second interlayer dielectric disposed between the first lower source/drain pattern and the first upper source/drain pattern, wherein
the first source/drain contact extends in the first direction through the second interlayer dielectric and is connected to the first lower source/drain pattern.

8. The semiconductor device according to claim 1, wherein the first source/drain contact includes a filling layer and a conductive liner layer surrounding a side surface of the filling layer and a lower surface of the filling layer.

9. The semiconductor device according to claim 1, wherein the first spacer and the first interlayer dielectric are formed of different materials.

10. The semiconductor device according to claim 1, wherein the second source/drain contact overlaps with at least a portion of the second upper source/drain pattern in the second direction.

11. The semiconductor device according to claim 1, further comprising a third source/drain contact extending in the first direction through the lower insulating layer, and connected to the second lower source/drain pattern.

12. The semiconductor device according to claim 11, wherein the third source/drain contact is in contact with a lower surface of the second lower source/drain pattern.

13. A semiconductor device, comprising:
a lower insulating layer;
a lower channel pattern stacked on the lower insulating layer in a first direction;
an upper channel pattern spaced apart from the lower channel pattern in the first direction;
a lower gate structure surrounding the lower channel pattern;
an upper gate structure surrounding the upper channel pattern;
a first lower source/drain pattern disposed on a first side of the lower gate structure in a second direction that intersects the first direction, and a second lower source/drain pattern disposed on a second side of the lower gate structure in the second direction;
a first upper source/drain pattern disposed on a first side of the upper gate structure in the second direction, and a second upper source/drain pattern disposed on a second side of the upper gate structure in the second direction;
a first spacer disposed on the first upper source/drain pattern;
a first interlayer dielectric disposed on the second upper source/drain pattern;
a first source/drain contact extending along a first side surface of the first spacer in the first direction, the first source/drain contact extending through the first spacer and the first upper source/drain pattern, and connected to the first upper source/drain pattern, wherein the first source/drain contact is in contact with an upper surface of the first lower source/drain pattern; and
a second source/drain contact extending along a side surface of the first interlayer dielectric in the first direction, extending through the first interlayer dielectric, and connected to the second upper source/drain pattern, wherein
the first spacer and the first interlayer dielectric are formed of different materials,
the second source/drain contact overlaps with at least a portion of the second upper source/drain pattern in the second direction,
the first side of the lower gate structure and the first side of the upper gate structure face a first side of the semiconductor device in the second direction; and
the second side of the lower gate structure and the second side of the upper gate structure face a second side of the semiconductor device opposite the first side of the semiconductor device in the second direction.

14. The semiconductor device according to claim 13, further comprising:
a second spacer disposed on a side surface of the upper gate structure; and
an etch stop layer disposed between the first spacer and the second spacer, wherein
the etch stop layer contacts a second side surface of the first spacer opposite the first side surface of the first spacer, and extends along a bottom surface of the first spacer.

15. The semiconductor device according to claim 14, wherein the etch stop layer and the first spacer include the same insulating material.

16. The semiconductor device according to claim 14, wherein a thickness of the first spacer in the second direction is greater than a thickness of the etch stop layer in the second direction at a position in the first direction where the etch stop layer contacts the second side surface of the first spacer.

17. The semiconductor device according to claim 13, further comprising:
a second interlayer dielectric disposed between the first lower source/drain pattern and the first upper source/drain pattern, wherein
the first source/drain contact extends in the first direction through the second interlayer dielectric in the first direction and is connected to the first lower source/drain pattern.

18. The semiconductor device according to claim 13, further comprising a third source/drain contact extending in the first direction through the lower insulating layer, and connected to the second lower source/drain pattern.

19. The semiconductor device according to claim 18, wherein the third source/drain contact is in contact with a lower surface of the second lower source/drain pattern.

20. A semiconductor device, comprising:
a lower insulating layer;
a lower channel pattern stacked on the lower insulating layer in a first direction;
an upper channel pattern spaced apart from the lower channel pattern in the first direction;
a lower gate structure surrounding the lower channel pattern;
an upper gate structure surrounding the upper channel pattern;
a first lower source/drain pattern disposed on a first side of the lower gate structure in a second direction that intersects the first direction;
a second lower source/drain pattern disposed on a second side of the lower gate structure in the second direction;
a first upper source/drain pattern spaced apart from the first lower source/drain pattern in the first direction and disposed on a first side of the upper gate structure in the second direction;
a second upper source/drain pattern spaced apart from the second lower source/drain pattern in the first direction and disposed on a second side of the upper gate structure in the second direction;
a first interlayer dielectric disposed on the second upper source/drain pattern;
a second interlayer dielectric disposed between the lower channel pattern and the upper channel pattern;
an etch stop layer disposed on the first upper source/drain pattern;
a first spacer disposed on the etch stop layer;
a first source/drain contact extending along a side surface of the first spacer and the etch stop layer in the first direction, extending through the first spacer, the etch stop layer, the first upper source/drain pattern, and the second interlayer dielectric, and connected to the first upper source/drain pattern and the first lower source/drain pattern; and
a second source/drain contact extending along a side surface of the first interlayer dielectric in the first direction, extending through the first interlayer dielectric, and connected to the second upper source/drain pattern, wherein
a thickness of the first spacer in the second direction is different from a thickness of the first interlayer dielectric in the second direction;
the first side of the lower gate structure and the first side of the upper gate structure face a first side of the semiconductor device in the second direction; and
the second side of the lower gate structure and the second side of the upper gate structure face a second side of the semiconductor device opposite the first side of the semiconductor device in the second direction.
